(19) United States
(12) Patent Application Publication
(10) Pub. No.: US 2012/0175652 A1
(43) Pub. Date: Jul. 12, 2012

(54) METHOD AND APPARATUS FOR IMPROVED SINGULATION OF LIGHT EMITTING DEVICES

(75) Inventors: Irving Chyr, Fremont, CA (US); Jonathan Halderman, Santa Clara, CA (US); Juan Chacin, San Jose, CA (US)

(73) Assignee: ELECTRO SCIENTIFIC INDUSTRIES, INC., Portland, OR (US)

(21) Appl. No.: 12/985,904

(22) Filed: Jan. 6, 2011

(51) Int. Cl. H01L 33/22; B23K 26/00; H01L 21/268

(52) U.S. Cl. 257/98; 438/33; 438/795; 219/121.67; 257/E21.347; 257/E33.074

(57) ABSTRACT

The present invention is a system and method for laser-assisted singulation of light emitting electronic devices manufactured on a substrate, having a processing surface and a depth extending from the processing surface. It includes providing a laser processing system having a picosecond laser having controllable parameters; controlling the laser parameters to form light pulses from the picosecond laser, to form a modified region having a depth which spans about 50% of the depth and substantially including the processing surface of the substrate and having a width less than about 5% of the region depth; and, singulating the substrate by applying mechanical stress to the substrate thereby cleaving the substrate into said light emitting electronic devices having sidewalls formed at least partially in cooperation with the linear modified regions.

### TECHNICAL FIELD

The present invention relates to laser-assisted singulation of light emitting devices manufactured on a common substrate. Particularly, this invention relates to singulation of light emitting devices using a picosecond laser directed to create modified regions which begin on the surface of the substrate in alignment with the modified regions and extend into the interior. More particularly, this invention relates to singulation of light emitting devices having textured surfaces to enhance the light emitting properties of the devices.

### BACKGROUND OF THE INVENTION

Electronic devices are typically manufactured by building multiple copies of the device in parallel on a common substrate and then separating or singulating the devices into separate units. The substrates include wafers of silicon or sapphire combined with layers of metallic (conducting), dielectric (insulating), or semi-conducting materials to form electronic devices. FIG. 1 shows a typical wafer 10 supporting devices 12 laid out in rows and columns. These rows and columns form streets 14, 16 or straight lines between the devices 12. This arrangement of devices 12 and streets 14, 16 allows the wafer to be separated along straight lines which permits the use of rotary mechanical saws and mechanical cleaving. Desirable properties for singulation techniques include small kerf size to reduce street size and thereby permit more active device area per substrate, smooth undamaged edges which increase die break strength, which is a measure of the ability of a singulated device to resist failure under mechanical stress, and system throughput, which is the number of wafers which can be processed with acceptable quality per unit time and is typically related to the cutting speed and number of passes per cut. Substrates can be singulated by dicing, which is a process by which a cutting tool such as a saw blade is used to cut completely through the substrate along the streets in rows and columns thereby singulating the substrate into individual devices. Substrates can also be scribed, which is a process by which a cutting tool cuts a scribe or shallow trench in the surface of the substrate and then force is applied, typically mechanically, to separate or cleave the substrate by forming cracks which start at the scribe. Typically semiconductor wafers to be singulated are temporarily attached to a stretchable adhesive film sometimes referred to as die attach film (DAF) held by an encircling frame. This DAF permits the wafer to be singulated while still maintaining control of the individual devices.

Important factors in device singulation for light emitting devices such as light emitting diodes (LEDs) or laser diodes include die break strength, which is the amount of flexing a singulated device can withstand without damage and is at least partially a function of the singulation process. Singulation processes that cause damage in the singulated edge of the material as a result of the heat affected zone (HAZ) that can surround a laser pulse location can reduce the die break strength of the resulting singulated device. Finally, light output of the device as a function of electrical energy applied is an important factor in determining the quality of the singulated device. Light output from a light emitting device is at least partly a function of the singulation process since the optical properties of the resulting edge is a determinant of the light output, since the edge quality determines how much light is reflected back into the device and how much light is usefully transmitted out of the device. Factors which determine edge quality include the presence of thermal debris, random faceting of the cleaved edge and damage to the edge caused by the HAZ. Finally, system throughput, which is the number of devices which can be singulated per unit time on a given machine, is an important factor in determining the desirability of a singulation technique. Techniques which increase quality but at the cost of a decrease in system throughput will be less desirable than techniques which do not reduce system throughput.

Lasers have been advantageously applied to singulation of electronic devices. Lasers have the advantages of not consuming expensive diamond coated saw blades, can cut substrates faster with smaller kerfs than saws and can cut patterns other than straight lines if required. Problems with lasers include damage caused to devices by excessive heat and contamination from debris. U.S. Pat. No. 6,676,878; LASER SEGMENTED CUTTING; inventors James N. O'Brien, Lian-Cheng Zou and Yunlong Sun; assigned to the assignee of this patent application; discusses ways of singulating wafers using multiple passes of ultraviolet (UV) laser pulses to increase system throughput while maintaining device quality by controlling heat buildup. Effects of singulation on light output of light emitting devices is not discussed in this patent. U.S. Pat. No. 7,804,043; METHOD AND APPARATUS FOR DICING OF THIN AND ULTRA THIN SEMICONDUCTOR WAFER USING ULTRAFAST PULSE LASER; inventor Tan Deshi discusses using ultrafast (femtosecond or picosecond) pulse durations to control debris creation. The '043 patent discloses that ultrafast pulses can permit scribing or dicing wafers without creating large amounts of thermal debris. The effect this debris can have on light output from light emitting devices is not discussed in the '043 patent. Apparently, ultrafast pulses can couple energy into the materials to be removed fast enough that the energy of the pulse is used to substantially ablate the materials rather than thermally remove them. Ablation is a process by which material is removed from a substrate by coupling enough energy into the material quickly enough that the atoms of the material are disassociated into a plasma cloud of charged molecules, nuclei, and electrons. This is in contrast to thermal material removal where the material is either melted into a liquid and then vaporized into a gas or sublimated directly into a gas by the laser energy. In addition, thermal material removal can also remove material from the laser machining site by ejecting liquid or solid material from the expansion of heated gases at the site. In practice any laser material removal is generally a combination of both ablative and thermal processes. Highly energetic laser pulses with short pulse duration tend to cause the material removal to be more ablative than thermal. The same pulse energy applied over a longer pulse duration will tend to cause material removal to be more thermal than ablative.

Laser-assisted singulation of light emitting devices presents challenges since the quality of the edge left on the device by the singulation process can affect the light output and therefore the value of the finished device. U.S. Pat. No. 6,580,054; SCRIBING SAPPHINRE SUBSTRATES WITH A SOLID STATE LASER; inventors Kuo-Ching Liu, Pei Hsien Fang, Dan Dere, Jenn Liu, Jih-Chuang Huang, Antonio Lucero, Scott Pinkham, Steven Oltrogge, and Duane Middlebusher, assigned to the assignee of this patent application, discusses using UV laser pulses to scribe sapphire substrates used to manufacture light emitting diodes. U.S. Pat. No. 6,992,026; LASER PROCESSING METHOD AND LASER PROCESSING APPARATUS; inventors Fumitsugo Fukuyo, Kenshi Fukumitsu, Kaoki Uchiuyama and Toahimitsu Wakuda; discusses forming deteriorated regions within the wafer to guide the mechanical cleaving and leave the surface of the wafer undamaged following singulation. None of the patents mentioned herein discuss the effects of laser assisted singulation on device edge optical quality or its effect on light output.

A reference which discusses edge quality and its optical properties is an article titled Efficiency Enhancement of GaN-Based Power-Chip LEDs with Sidewall Roughness by Natural Lithography; authors Hung-Wen Huang, C. F. Lai, W. C. Wang, T. C. Lu, H. C. Kuo, S. C. Wang, R. J. Tsai and C. C Yu; Electrochemical and Solid State Letters, Vol. 10 No. (2). This article discusses light output of a light emitting diodes (LED) as a function of sidewall roughness. This article discloses controlling sidewall roughness by adding the additional step of etching with polystyrene beads. The step of etching with polystyrene beads adds new equipment, requirements unrelated the fundamental task of singulating light emitting devices, and thus cost to the process and reduces throughput of the overall process. The authors of the article apparently did not contemplate or understand that sidewall quality could be favorably affected or controlled with a laser during singulation.

There remains a continuing need for a cost efficient, reliable, and repeatable method for laser assisted singulation of light emitting devices from a substrate which controls sidewall quality to provide improved light output from the devices while maintaining device quality and system throughput.

### SUMMARY OF THE INVENTION

The present invention is a system and method for laser-assisted singulation of light emitting electronic devices manufactured on a substrate, having a processing surface and a depth extending from the processing surface. It includes providing a laser processing system having a picosecond laser having controllable parameters; controlling the laser parameters to form light pulses from the picosecond laser, to form a modified region having a depth which spans more than 50% of the depth and substantially including the processing surface of the substrate and having a width less than about 5% of the region depth; and, singulating the substrate by applying mechanical stress to the substrate thereby cleaving the substrate into said light emitting electronic devices having sidewalls formed at least partially in cooperation with the linear modified regions. Aspects of this invention perform laser assisted singulation of light emitting electronic devices manufactured on a substrate with a laser processing system. The laser processing system uses a pulsed picosecond laser having controllable laser parameters to form a modified region on the surface of the substrate which extends into the interior of the substrate, the laser parameters being controlled to limit the extent of the modified region laterally. The substrate is then singulated by applying mechanical stress to the substrate proximate to the modified region thereby cleaving the substrate along facets which include the modified regions. These facets which include modified materials are operative to transmit more than about 80% of the light impinging upon them emitted by the light emitted device.

Aspects of this invention improve light output from singulated light emitting devices by using laser pulse parameters that reduce the amount of thermal debris and control the heat damage to the substrate. Laser pulses with 532 nm wavelength, or shorter, with pulse widths of less than about 10 ps emitted at a pulse repetition in the 75 kHz to 800 kHz range are advantageously used to scribe sapphire substrates. The laser pulses are delivered to the substrate using an adapted laser scribing system. These pulses are focused to a less than about 1 micron to about 5 micron focal spot which is positioned with respect to the substrate by cooperation between the adapted laser scribing system's beam positioning optics and the motion control stages. The laser parameters are adjusted so that desirable changes in substrate materials occur in and adjacent to the focal spot and minimum undesirable changes occur in the material around the focal spot. Desirable effects of the laser pulses include altering the molecular or crystalline structure of the material to enhance crack initiation or propagation and providing a predetermined amount of texture to the irradiated edge following cleaving. By properly selecting laser pulse parameters, the modifications made to the substrate materials can enhance crack initiation and propagation so that reduced mechanical force is required to cleave the material following laser scribing, thereby reducing the chances of chipping and other undesirable effects of cleaving. Further undesirable effects include damage caused by a heat affected zone (HAZ) near the irradiated location and thermal debris. HAZ damage includes creation of microcracks which reduce die break strength and creation of edge regions which absorb and reflect light back into the device, thereby reducing light output. Thermal debris also absorbs and reflects light back into the device, also reducing light output. Aspects of this invention employ laser parameters which promote the formation of modified regions in the substrate with just enough deteriorated or modified materials to form a textured surface which promotes light transmission through the sidewalls but does not extend far enough laterally to inhibit light transmission.

Aspects of this invention create scribes on substrates with desirable properties by employing picosecond laser pulses and directing them to the substrate in such a fashion that repeated laser pulses directed to the same vicinity on the substrate to form the scribes cause desirable changes in the substrate but do not raise the temperature of the HAZ enough to cause undesired thermal damage. This is accomplished by selecting laser parameters in addition to the wavelength, pulse duration, repetition rate, pulse energy and focal spot size listed above. These laser parameters include the timing and spacing of adjacent laser pulses on the substrate as the laser is pulsed while the laser beam is moved with respect to the substrate, which is dependent on laser repetition rate, pulse duration and is typically expressed in mm/s. Typical laser beam speeds for embodiments of this invention range from 20 to 1000 mm/s or more particularly from 50 to 450 mm/s.

Aspects of this invention cleave the scribed substrate by applying mechanical stress to the substrate in proximity to the linear modified regions to initiate cracks which separate the substrate along the modified regions. Having a scribe on the surface of the substrate to initiate and guide the mechanical cleaving process provides a resulting sidewall surface with better optical properties than if the cracks are begun in modified regions which do not reach the surface. Stress applied generally to the substrate by mechanically stretching the DAF or by using a mechanical cleaving tool such as an Opto-System Semi Auto Breaker WBM-1000, manufactured by Opto-System Co. Ltd., Kyoto, Japan 610-0313, will cause cracks to begin in the scribe regions and propagate through the substrate. Cleaving performed on substrates with interior scribes without surface scribes tend to propagate cracks in random directions towards the surface, causing multiple facets which are defined as small regions of the edge with a common surface orientation. These multiple random facets tend to reflect more light back into the singulated device thereby diminishing light output. Cleaving substrates with surface scribes tends to create an edge with facets which reflect less light back into the device thereby increase light output because the resulting facets are generally aligned parallel to the scribing direction. Embodiments of this invention singulate a substrate by cleaving along scribes made on the surface of the substrate and which extend into the substrate.

### BRIEF DESCRIPTION OF THE DRAWINGS

FIG. 1 Wafer

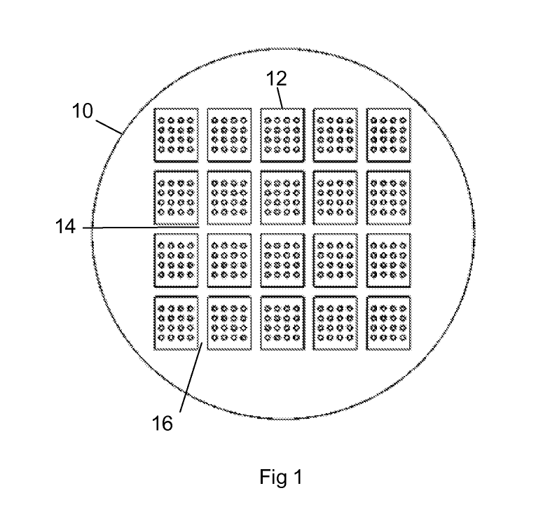

FIG. 2 Laser processing system

FIG. 3 Scribed substrate

FIG. 4 SEM image of scribed substrate

FIG. 5 SEM image of scribed substrate

### DETAILED DESCRIPTION OF PREFERRED EMBODIMENTS

Aspects of this invention perform laser assisted singulation of light emitting electronic devices manufactured on a substrate with a laser processing system. The laser processing system uses a pulsed picosecond laser having controllable laser parameters to form a modified region on the surface of the substrate which extends into the interior of the substrate, the laser parameters being controlled to limit the extent of the modified region laterally. The substrate is then singulated by applying mechanical stress to the substrate proximate to the modified region thereby cleaving the substrate along facets which include the modified regions. These facets which include modified materials improve the light output from the light emitting device by providing a highly transmissive, diffuse, non-specular sidewall surface which improves the transmission of light from the interior of the device to the outside. Light which is reflected back into the device is undesirable first because it does not contribute to the useful light output of the device and secondly because it could be potentially re-absorbed and contribute to unwanted heat build-up which further reduces the efficiency of the device. Aspects of this invention achieve improved light output efficiency of light emitting devices by improving the light transmitting abilities of device sidewalls as a result of the particular manner in which the substrate containing the devices is laser scribed in preparation for cleaving. Scribing a substrate containing light emitting devices with properly selected laser parameters will provide modified regions with desirable light transmitting properties on the sidewalls formed by the singulation process.

Aspects of this invention improve light output from singulated light emitting devices by using laser pulse parameters that reduce the amount of thermal debris and heat damage to the substrate. Laser pulses with wavelengths in the range of 150 to 3000 nm, or more particularly in the range from 150 to 600 nm, with pulse widths less than 10 ns or more particularly less than 300 ps emitted at a pulse repetition rate in the 3 to 1500 kHz range, or more particularly in the 75 to 600 kHz range are advantageously used to scribe substrates. The pulses are focused to focal spots in the range of less than about 1 micron to about 25 microns, more particularly in the range from less than 1 micron to about 2 microns. The laser is delivered to the substrate using an adapted AccuScribe 2600 LED Laser Scribing System, manufactured by Electro Scientific Industries, Inc., Portland, Oreg. 97239. One of the adaptations made is fitting a solid state IR laser model Duetto manufactured by Time-Bandwidth Products AG, CH-8005 Zurich, Switzerland. This laser emits 10 ps pulses at 1064 nm wavelength which are frequency-doubled using a solid-state harmonic generator to 532 nm wavelength and optionally frequency tripled using a solid-state harmonic generator to 355 nm wavelength. Optionally, a Lumera Rapid Green laser model SHG-SS manufactured by Lumera Laser GmbH, Opelstr. 10, 67661 Kaiserslautern, Germany may be fitted onto the AccuScribe 2600 LED Laser Scribing System in place of the Time-Bandwidth Duetto. The Lumera laser emits 10 ps pulses at 1064 nm and 532 nm wavelengths. The dual output of the Lumera laser may be used to create 355 nm output using a solid-state harmonic generator. These lasers have output power of 0.1 to 1.5 Watts.

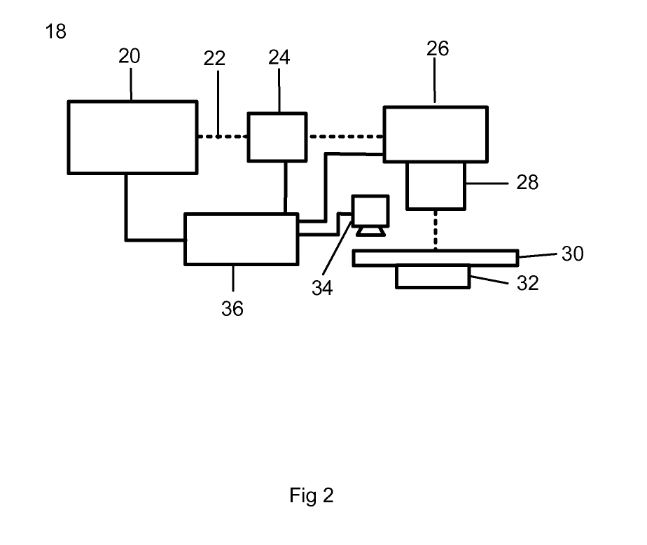

FIG. 2 shows a diagram of a laser scribing system 18 adapted to scribe substrates 30 according to embodiments of this invention. The adapted laser scribing system 18 has a laser 20 operative to emit laser pulses 22. These pulses are shaped and steered by the beam shaping and steering optics 24 and then directed to the substrate 30 by the field optics 26. The debris control nozzle 28 uses vacuum and compressed air to keep debris created by the scribing process from settling back down on the surface of the substrate. The substrate 30 is moved with respect to the laser pulses by the motion control stages 32 working in cooperation with the beam shaping and steering optics 24. In addition an imaging system 34 including objective optics is used to align the substrate 30 with respect to the laser pulses 22. The laser 20, the beam shaping and steering optics 24, the motion control stages 32 and the imaging system 34 all operate under the control of the system controller 36.

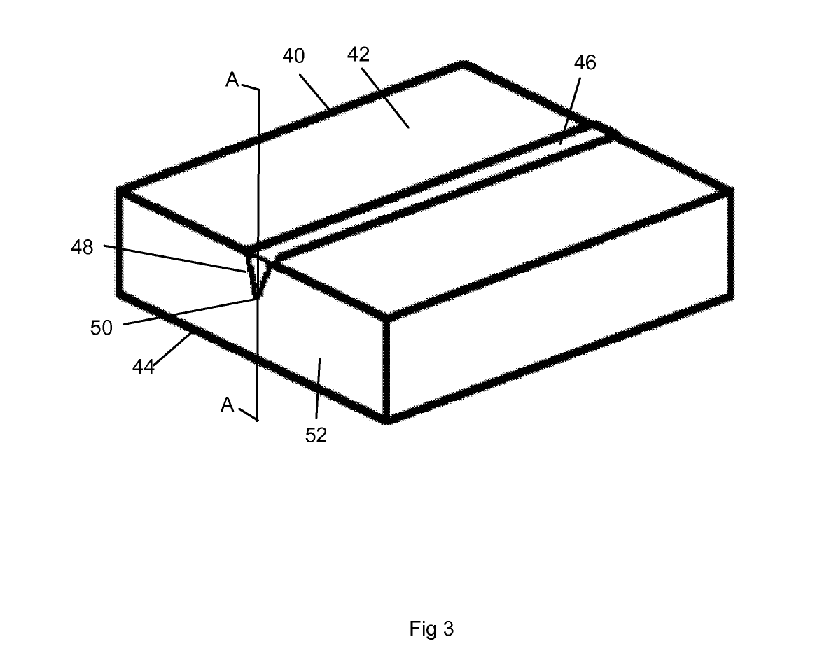

FIG. 3 shows a section of a substrate 40 having a top surface 42 and a bottom surface 44. On the top surface 42 of the substrate a scribe 46 is formed by laser pulses 22 focused to a less than about 1 micron to 5 micron focal spot which is positioned with respect to the substrate 40 by cooperation between the adapted laser scribing system's 18 beam shaping and steering optics 24 and the motion control stages 32. The pulses are focused to a spot on or near the surface 42 to perform scribing. The laser parameters are adjusted so that desirable changes in substrate materials occur in and adjacent to the focal spot and minimum undesirable changes occur in the material around the focal spot to form a volume of modified material 48 which extends into the substrate 40 a distance 50 from the top surface 42. This modified region 48 is visible in the sidewall 52 perpendicular to the linear direction of the scribe and describes the lateral extent of the material modified by the laser. Desirable effects of the laser pulses include altering the molecular or crystalline structure of the material to enhance crack initiation or propagation and providing texture to the irradiated edge following cleaving. Cleaving will occur linearly along the scribe and vertically along the line AA when mechanical stress is applied to the substrate in the proximity of the scribe. Undesirable effects include damage caused by a heat affected zone (HAZ) near the irradiated location and thermal debris. HAZ damage also includes creation of microcracks which reduce die break strength and creation of edge regions which absorb and reflect light back into the device, thereby reducing light output. Thermal debris also absorbs and reflects light back into the device, also reducing light output. By use of preselected laser parameters, these negative effects of laser scribing can be minimized while the desired effects can be achieved.

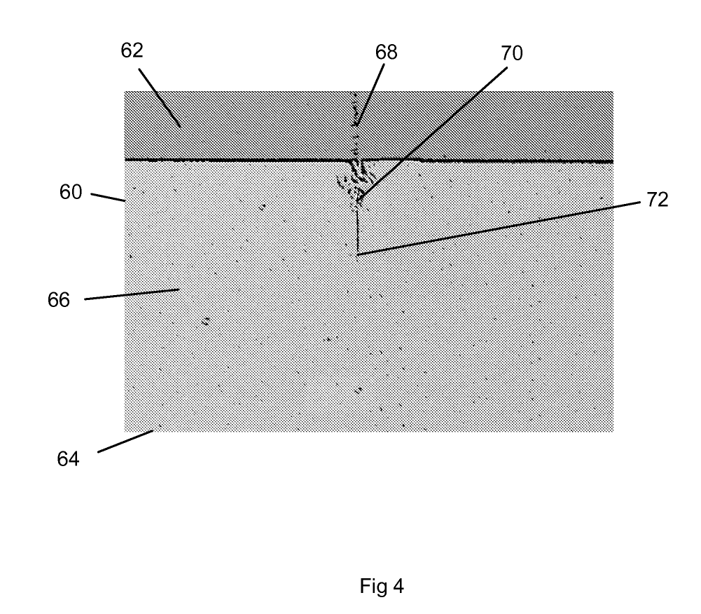

Aspects of this invention create scribes on substrates with desirable properties by employing picosecond laser pulses and directing them to the substrate in such a fashion that repeated laser pulses directed to the same vicinity on the substrate cause desirable changes in the substrate but do not raise the temperature of the HAZ enough to cause undesired thermal damage. This is accomplished by selecting laser parameters in addition to the wavelength, pulse duration, repetition rate, pulse energy and focal spot size listed above. These laser parameters include the timing and spacing of adjacent laser pulses on the substrate as the laser is pulsed while the laser beam is moved with respect to the substrate, which is dependent on laser repetition rate, pulse duration and is typically expressed in mm/s. Typical laser beam speeds for embodiments of this invention range from 20 to 1000 mm/s or more particularly from 50 to 450 mm/s. FIG. 4 shows a scanning electron microscope image of a wafer scribed according to an embodiment of this invention. FIG. 4 shows a scribed substrate 60, viewed perpendicular to the sidewall 52. This view shows the top surface of the substrate 62 and the bottom 64, along with the sidewall 66. The top surface 62 shows the scribe 68 with modified material 70 interior to the substrate 60 visible on the sidewall 52. The modified region extends into the substrate a distance 72. Note that the lateral extent of the modified material visible in this image shows that the vertical extent of the modifications is greater than the lateral extent, perpendicular to the linear scribe.

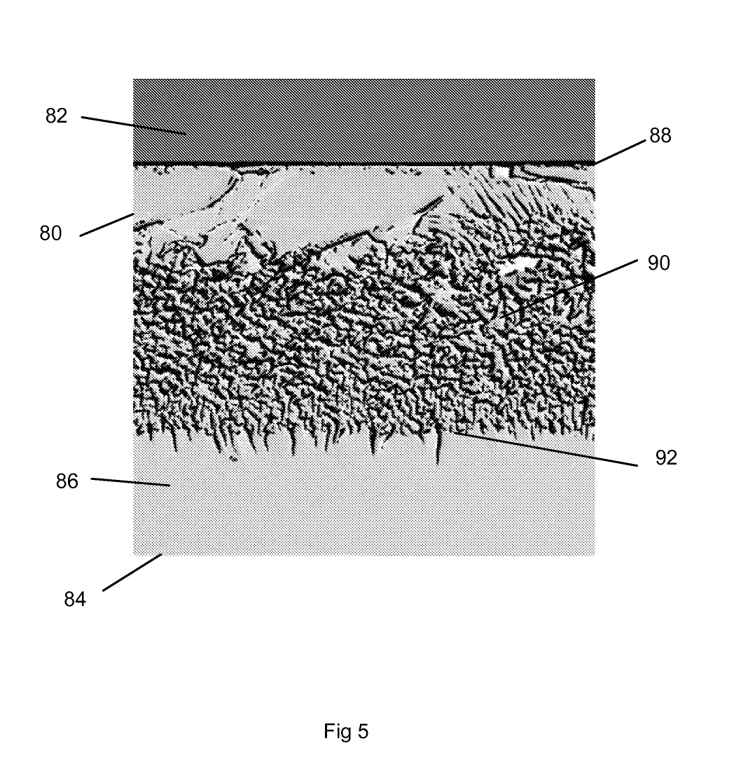

Aspects of this invention cleave the scribed substrate by applying mechanical stress to the substrate proximate to the scribe on the surface of the substrate to initiate and guide the mechanical cleaving process. Stress applied generally to the substrate by mechanically stretching the DAF or by using a mechanical cleaving tool such will cause cracks to begin in the modified scribe regions and propagate through the substrate from top surface to bottom surface. Cleaving performed on substrates with interior scribes without adjacent surface scribes tend to propagate cracks in random directions towards the surface, causing multiple facets which are defined as small regions of the edge with a common surface orientation. These multiple random facets tend to reflect more light back into the singulated device thereby diminishing light output. Cleaving substrates with surface scribes permits the cracks to propagate to the scribe on the surface creating an edge with facets which reflect less light back into the device thereby increase light output because the resulting facets are generally aligned parallel to the scribing direction. FIG. 5 shows a scanning electron microscope image of a substrate following scribing according to an embodiment of this invention. FIG. 5 shows a substrate 80 having a top surface 82 and a bottom 84, with a sidewall 86 formed by cleaving a substrate along a line similar to AA in FIG. 3 parallel to the linear direction of the scribe. This image shows the location of the scribe 88, along with the modified region 90 revealed on the sidewall 86 by cleaving. The modified region extends a distance 92 into the substrate. This modified region which forms at least part of the sidewall is operative to transmit light originating in the device at a greater efficiency than sidewalls without this texture or sidewalls with modified regions which extend into the substrate laterally more than a few microns.

Embodiments of this invention are used to scribe substrates which may be substantially transparent to the laser wavelengths employed by the system. In particular, sapphire wafers used as substrates to manufacture light emitting diodes are substantially transparent to the wavelengths of laser light used by a preferred embodiment of this invention. Sapphire wafers transmit about 85% of the laser energy at wavelengths between 355 nm and 4000 nm and greater than 60% of the laser energy at wavelengths between 190 nm and 355 nm). It is also typical for the substrate to have the DAF applied to the top surface of the substrate which contains the active circuitry. It is also often desirable to scribe the substrate on the top surface in the streets between the active devices. In this case the DAF with attached substrate is loaded into the system so that the laser pulses impinge the substrate on the surface opposite to where the scribe is desired. Since the substrate is substantially transparent to the laser wavelengths used, the laser pulses can be transmitted through the substrate and focused on the opposite surface of the substrate. Since the laser pulses only have enough energy to cause material modifications where the focal spot intersects the substrate, scribing or modification will take place near the surface opposite to where the laser pulses impinge the substrate.

It will be apparent to those of ordinary skill in the art that many changes may be made to the details of the above-described embodiments of this invention without departing from the underlying principles thereof. The scope of the present invention should, therefore, be determined only by the following claims.

We claim:

1. An method for laser-assisted singulation of light emitting electronic devices manufactured on a substrate, having a processing surface and a depth extending from said processing surface, said method comprising:
providing a laser processing system having a picosecond laser having selectable parameters;
selecting said laser parameters to form light pulses from said picosecond laser, to form a modified region having a depth which spans more than about 50% of said depth and substantially including said processing surface of said substrate and having a width less than about 5% of said region depth; and, singulating said substrate by applying mechanical stress to said substrate thereby cleaving said substrate into said light emitting electronic devices having sidewalls formed at least partially in cooperation with said linear modified regions.

2. The method of claim 1 wherein said laser parameters include at least one of wavelength, pulse duration, pulse energy, pulse repetition rate, focal spot size, focal spot offset, and focal spot speed.

3. The method of claim 2 wherein the wavelength is equal to or shorter than about 600 nm.

4. The method of claim 2 wherein the pulse duration is equal to or shorter than about 100 ps.

5. The method of claim 2 wherein the pulse energy equal to or greater than about 1.0 microJoules.

6. The method of claim 2 where the pulse repetition rate is between about 75 Hz and about 600 kHz.

7. The method of claim 2 where the focal spot size is between less than about 1 micron to about 5 microns.

8. The method of claim 2 where the focal spot offset is between −50 microns and +50 microns relative to said substrate surface.

9. The method of claim 2 where the focal spot speed is between about 25 and about 450 mm/s relative to said substrate surface.

10. A laser scribing system for laser-assisted singulation of light emitting electronic devices manufactured on a substrate having a processing surface and a depth extending from said processing surface, said system comprising:
a picosecond laser adapted to produce light pulses having at least one selectable parameter;
laser optics to controllably deliver said light pulses to said substrate;
motion control stages to controllably move said substrate in relation to said pulses; and,
a controller that directs said picosecond laser to emit said pulses, directs said laser optics to deliver said pulses to said substrate and directs said motion stage to move said substrate in relation to said pulses with said parameters operative to form modified regions having a depth which spans 50% of said depth and substantially including said processing surface of said substrate and having a width less than about 5% of said region depth.

11. The system of claim 10 where said laser parameters include at least one of wavelength, pulse duration, pulse energy, pulse repetition rate, focal spot size, focal spot offset, and focal spot speed.

12. The system of claim 11 where the wavelength is equal to or shorter than about 600 nm.

13. The system of claim 11 where the pulse duration is equal to or shorter than about 100 ps.

14. The system of claim 11 where the pulse energy is equal to or greater than about 1.0 microJoule.

15. The system of claim 11 where the pulse repetition rate is between about 75 Hz and about 600 kHz.

16. The system of claim 11 where the focal spot size is between about less than 1 micron and about 5 microns.

17. The system of claim 11 where the focal spot offset is between −50 microns and +50 microns relative to said substrate surface.

18. The system of claim 11 where the focal spot speed is between about 25 and about 450 mm/s relative to said substrate surface.

19. An improved light emitting electronic device having sidewalls, singulated from a substrate having a processing surface and a depth extending from said processing surface with a laser scribing system having a laser having selectable parameters, said improvements comprising:
texturing said sidewalls by controlling said laser parameters to create modified regions with said laser that extend from the surface of said substrate to the interior of said substrate to permit greater light output and thereby improve said light emitting electronic device.

20. The method of claim 1, further comprising: said modified regions having a depth which spans 50% of said depth and substantially including said processing surface of said substrate and having a width less than about 5% of said region depth

20. A method of texturing a surface of a light emitting device to be singulated comprising:
applying laser pulses having selectable parameters, said parameters being selected to create modified regions on said surface which provide the desired texture.

21. The method of claim 20 where said laser parameters include at least one of wavelength, pulse duration, pulse energy, pulse repetition rate, focal spot size, focal spot offset, and focal spot speed.

22. The method of claim 21 where the wavelength is equal to or shorter than about 600 nm.

23. The method of claim 21 where the pulse duration is equal to or shorter than about 100 ps.

24. The method of claim 21 where the pulse energy is equal to or greater than about 1.0 microJoule.

25. The method of claim 21 where the pulse repetition rate is between about 75 and about 600 kHz.

26. The method of claim 21 where the focal spot size is between about less than about 1 micron and about 5 microns.

27. The method of claim 21 where the focal spot offset is between −50 microns and +50 microns relative to said substrate surface.

28. The method of claim 21 where the focal spot speed is between about 25 and about 450 mm/s relative to said substrate surface.
